(19) United States
(12) Patent Application Publication
(10) Pub. No.: US 2008/0094814 A1
(43) Pub. Date: Apr. 24, 2008

(54) Motherboard positioning apparatus for fast installation

(75) Inventor: Yin-Hung Chen, Taipei (TW)

Correspondence Address: BIRCH STEWART KOLASCH & BIRCH, PO BOX 747, FALLS CHURCH, VA, 22040-0747, US

(73) Assignee: Shuttle Inc.

(21) Appl. No.: 11/584,521

(22) Filed: Oct. 23, 2006

(51) Int. Cl. H05K 7/04; H05K 7/02

(52) U.S. Cl. 361/807

(57) ABSTRACT

A motherboard positioning apparatus for fast installation aims to position a motherboard on a chassis. The chassis has an elastic unit on one side wall and an anchor boss on the bottom thereof. The motherboard has one end pressing the anchor boss and another end urged by the elastic unit to be positioned on the bottom of the chassis. Thus with two ends of the motherboard held by the anchor boss and the elastic unit, the motherboard can be positioned quickly on a selected installation location on the chassis to facilitate fast and smooth installation of the motherboard.

### FIELD OF THE INVENTION

The present invention relates to a motherboard positioning apparatus and particularly to a design to position a motherboard on a chassis for fast installation.

### BACKGROUND OF THE INVENTION

In a conventional computer the motherboard usually is fastened to the host chassis through a plurality of screws. To position the motherboard quickly on the selected position on the chassis is difficult. A number of schemes have been proposed to align positioning holes of the motherboard with the fastening portion of the chassis to facilitate fastening of the screws. Reference of these fastening structures can be found in U.S. Pat. Nos. 4,523,883, 4,622,725 and 4,970,761, etc.

On modern computers the chassis usually has an I/O elastic dock on a side wall to hold the motherboard. During installation an elastic reed of the elastic dock presses one end of the motherboard. Such a design hinders installation. As workers have to press the motherboard against the elastic reed and hold the motherboard with one hand for positioning on the installation location to overcome the pushing force of the elastic reed (otherwise the motherboard will be skewed), and do fastening with other hand single-handedly. Such a process is inefficient. It creates a lot of problems for workers and takes more time to do installation of the motherboard.

### SUMMARY OF THE INVENTION

The primary object of the present invention is to provide a motherboard positioning apparatus that allows a motherboard to be positioned on a chassis at a selected location quickly to facilitate fastening or other installation operation in the follow on process, thereby to reduce installation time of the motherboard and increase installation efficiency.

To achieve the foregoing object, the invention provides an elastic unit on a side wall of the chassis. The chassis has an anchor boss on the bottom. One end of the motherboard is urged against the anchor boss while another end is pressed by the elastic unit to form a positioning condition. Hence the motherboard can be positioned quickly on the selected position of the chassis for installation.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of an embodiment of the invention.

FIG. 2 is an exploded view of an embodiment of the invention.

FIG. 3 is a sectional view of an embodiment of the invention.

FIG. 4 is a schematic view of another embodiment of the invention.

### DETAILED DESCRIPTION OF THE PREFERRED EMBODIMENTS

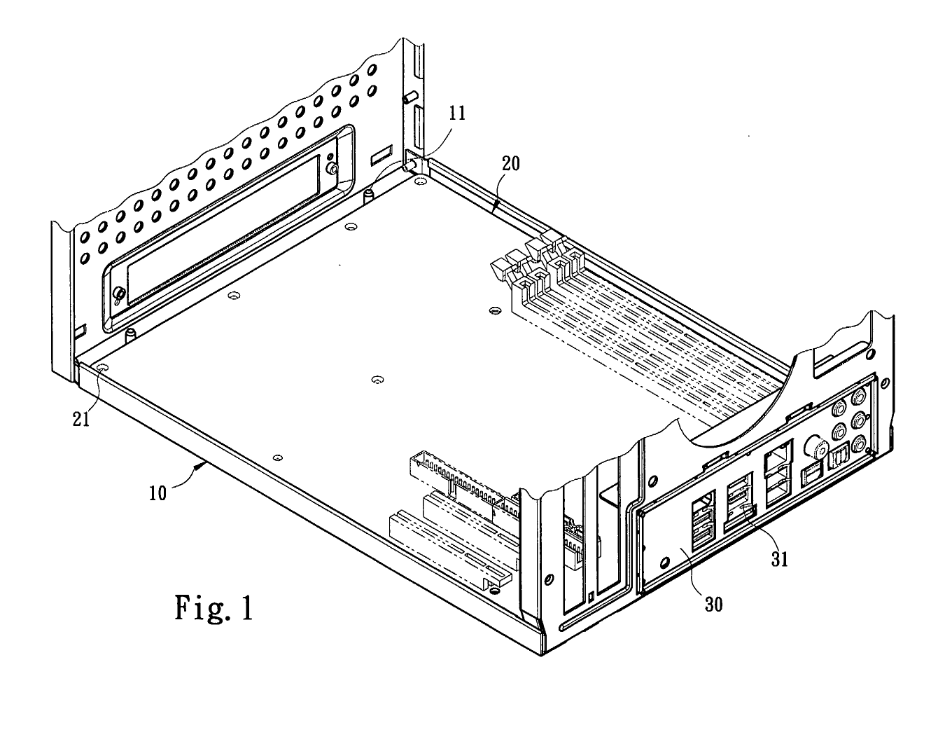

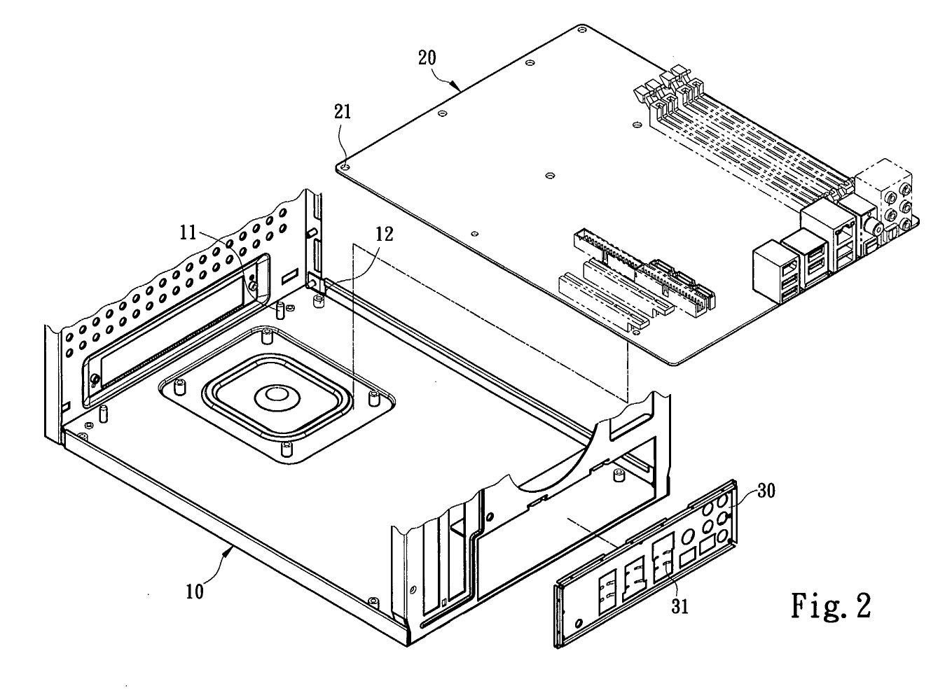

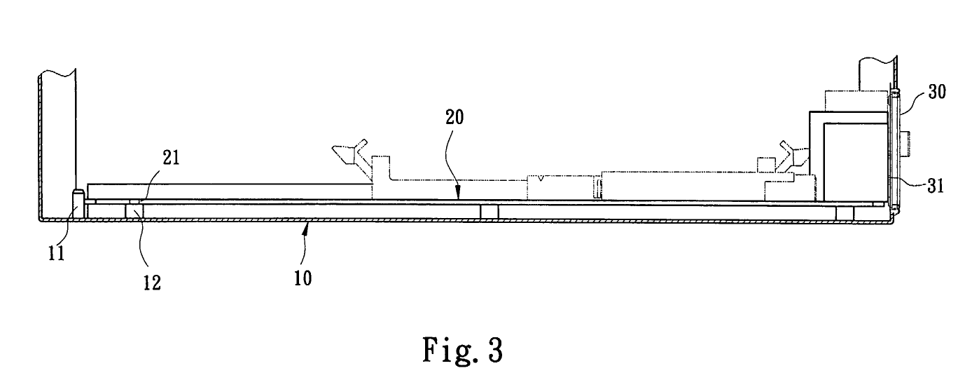

Please refer to FIGS. 1 and 2 for an embodiment of the invention. The motherboard positioning apparatus of the invention aims to position a motherboard 20 on a chassis 10. The chassis 10 has an elastic unit on a side wall. In this embodiment the elastic unit is an I/O elastic dock 30 on one side wall of the chassis 10. The I/O elastic dock 30 has an elastic reed 31 bending inwards to press one end of the motherboard 20. The chassis 10 further has a strut-like anchor boss 11 on the bottom to press another end of the motherboard 20. A fastening means is provided to form the positioning of the motherboard 20 on the chassis 10. The fastening means includes an anchor hole 21 on the motherboard 20 and a corresponding fastening portion 12 on the chassis 10 (referring to FIG. 3). The anchor hole 21 and fastening portion 12 may be coupled through a fastening element (not shown in the drawings) to fasten the motherboard 20 to the chassis 10 to facilitate fast installation. During installation, one end of the motherboard 20 is placed against the anchor boss 11, while another end is urged against the elastic reed 31 so that the motherboard 20 can be accurately positioned on a selected installation location. Namely, the anchor hole 21 of the motherboard 20 is corresponding to and coupled with the fastening portion 12 of the chassis 10 so that the motherboard 20 can be fastened to the chassis 10 through a fastening elements such as a screw.

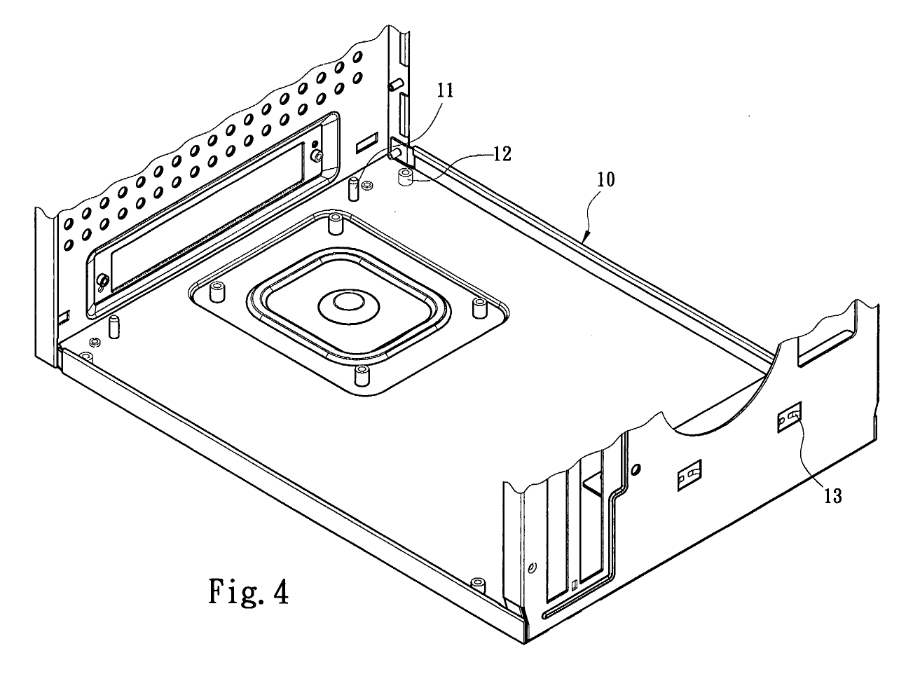

Aside from the I/O elastic dock 30, the elastic unit may also be another elastic reed 13 integrally formed by stamping the wall of the chassis 10 to press the motherboard 20 (referring to FIG. 4). In short, by providing the elastic unit on the side wall of the chassis 10 and anchor boss 11 on the bottom of the chassis 10, two ends of motherboard 10 can be urged on the anchor boss 11 and the elastic unit and quickly positioned on the selected installation position on the chassis 10. Therefore the follow on fastening and other installation activities can be performed rapidly. As a result, installation time of the motherboard 20 can be reduced, and installation of the motherboard 20 can be executed more smoothly.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A motherboard positioning apparatus for fast installation to position a motherboard on a chassis, comprising:
an elastic unit on one side wall of the chassis to press one end of the motherboard, the chassis having an anchor boss on the bottom to press another end of the motherboard to hold the motherboard, the apparatus further having a fastening means to fasten the motherboard to the chassis.

2. The motherboard positioning apparatus of claim 1, wherein the elastic unit is an I/O elastic dock located on the side wall of the chassis that has an elastic reed.

3. The motherboard positioning apparatus of claim 1, wherein the elastic unit is an integrated elastic reed formed by stamping the side wall of the chassis.

4. The motherboard positioning apparatus of claim 1, wherein the anchor boss is a strut located on the bottom of the chassis.

5. The motherboard positioning apparatus of claim 1, wherein the fastening means includes an anchor hole on the motherboard and a corresponding fastening portion on the chassis to position the motherboard.

6. The motherboard positioning apparatus of claim 5, wherein the anchor hole is engaged with a fastening element which is insertable into the coupling portion to fasten the motherboard to the chassis.
